(19) United States
(12) Patent Application Publication
(10) Pub. No.: US 2025/0218798 A1
(43) Pub. Date: Jul. 3, 2025

(54) METHODS AND DEVICES FOR PROCESSING SINGULATED SUBSTRATES

(71) Applicant: OCTAVO SYSTEMS LLC, Sugar Land, TX (US)

(72) Inventors: Erik WELSH, Bellaire, TX (US); Masood MURTUZA, Sugar Land, TX (US); Peter LINDER, Sugar Land, TX (US)

(73) Assignee: OCTAVO SYSTEMS LLC, Sugar Land, TX (US)

(21) Appl. No.: 19/002,016

(22) Filed: Dec. 26, 2024

Related U.S. Application Data
(60) Provisional application No. 63/616,134, filed on Dec. 29, 2023.

(51) Int. Cl. H01L 21/56

(52) U.S. Cl. CPC H01L 21/561; H01L 21/565

(57) ABSTRACT

Method and apparatus for manufacturing multiple singulated complex heterogeneous integrated (HI) or homogeneous integrated circuit devices using a Substrate Carrier Frame (SCF), having multiple nesting cavities in which singulated substrates are placed, and once the SCF has been populated, the manufacturing process of the substrates may proceed as if it were a strip, rather than as individual substrates one at a time.

### CROSS-REFERENCE TO RELATED APPLICATION(S)

This application claims priority to U.S. Provisional Application No. 63/616,134, filed Dec. 29, 2023, the entire disclosure of which is incorporated herein by reference.

### TECHNICAL FIELD

This disclosure relates to fabricating, assembling, and encapsulating substrates, and in particular, singulated substrates for heterogeneous integrated circuit devices.

### BACKGROUND

The electronics industry is entering a new era of integration. It is moving from designing electronic systems using hundreds of independent components, both active and passive, to using system components. These systems may contain many, if not all, of those components in one packaged device. The result of system level integration, also known as Heterogeneous Integration (HI), is the ability to reduce the size of the system.

Moreover, the performance of electronic systems is increasing while the power dissipation is decreasing, and the size is shrinking. To keep up with the shrinking of the system, the substrates (e.g., printed circuit boards) on which systems are integrated need to be updated. This can include aggressively shrinking their size, while increasing the density of the components on these substrates/circuit boards. Often the printed circuit boards (PCBs) and substrates used to manufacture integrated circuit devices, such as Systems on Module (SOM) devices, System in Package (“SiP”) devices, Multi-Chip Module (MCM) devices, and chiplets, increase in complexity as the number of components increases to integrate more functionality and capability. This can mean more layers in the PCB/substrate. Because of the need for more layers of electrical traces, there can also be more vias between the layers, and tighter design rules for spacing between traces in a layer.

Certain challenges exist. For instance, as a result of increased complexity, traditional semiconductor fabrication processes in which a strip of multiple tested good substrates for a particular device are assembled in bulk prior to being cut apart, could become cost prohibitive the increase in number of layers and tighter spacing of traces in a layer results in more fabrication defects in the substrates in a panel, resulting in more tested bad substrates in a panel.

To minimize the yield loss and address higher assembly costs, one approach has been to remove the good electrical substrates from the strip or panel of substrates and assemble, encapsulate, and attach external connectors one substrate (for a device) at a time. However, one area where this process becomes most cost prohibitive is at the encapsulation and external ball attach steps of the semiconductor fabrication process. A possible response is to attach lids rather than encapsulate the devices, which, in many designs, leaves all or portions of the lidded device open and unprotected from debris or chemicals that could affect the operation of the device.

There remains a need for improved methods and devices for processing singulated substrates.

### SUMMARY

According to embodiments, a method is provided that comprises loading a plurality of singulated substrates into a substrate carrier frame comprising a plurality of openings; and processing (e.g., encapsulating) the plurality of singulated substrates in the substrate carrier frame.

According to embodiments, a device comprises a substrate, at least one component mounted on the substrate, an encapsulant, and a piece of a substrate carrier frame.

According to embodiments, a substrate carrier device comprises a frame having a plurality of openings and a bottom plate below the plurality of openings. The openings are sized to receive a singulated substrate and the bottom plate is configured to support the singulated substrates.

According to embodiments, a substrate carrier device comprises a frame having a plurality of openings, and at least one retainer (e.g., tab or ledge) within each of the plurality of openings. In some embodiments, the openings are separated by one or more rib portions of the frame, and one or more mold channels are provided through the rib portions, where the mold channels connect two or more of the openings.

According to embodiments, an apparatus for containing one or more singulated substrates comprises a panel having a plurality of openings therein and alignment pins/holes suitable for use with semiconductor processing equipment, where each opening is sized to contain a singulated substrate.

These and other features of the disclosure will become apparent to those skilled in the art from the following detailed description of the disclosure, taken together with the accompanying drawings.

### BRIEF DESCRIPTION OF THE DRAWINGS

FIG. 1 illustrates an example of packaging a singulated substrate.

FIG. 2A-1 through FIG. 2E depict different views of a substrate carrier frame (SCF) according to some embodiments.

FIGS. 3A-3F depict one or more processes according to embodiments, such as the insertion and removal of a substrate carrier frame into a mold cavity.

FIGS. 4A-4F depict views of a substrate carrier frame according to embodiments after the substrates have been populated with components and encapsulated.

FIGS. 5A and 5B depict aspects of molding individual substrates using a disposable one-piece substrate carrier frame (e.g., for use in either a compression or transfer mold) according to embodiments. FIGS. 5C-5E depict aspects of three-piece substrate carrier frame.

FIGS. 6A-6D depict methods according to embodiments for manufacturing devices that have been singulated and processed using a substrate carrier frame.

FIG. 7 shows certain processing points in a semiconductor assembly used to create a System in Package (SiP) device.

FIG. 8 shows a SiP where a lid has replaced encapsulation.

FIG. 9 is a process according to some embodiments.

### DETAILED DESCRIPTION

Heterogeneous Integration (HI) enables integration of devices, with diverse fabrication technologies, such as for example, digital, analog, optical, and memory processes. Other devices may also be integrated which may be, for instance, active and/or passive devices and components (e.g., discrete circuits, sensors, and power management devices, and various non silicon devices as examples). Non-silicon devices could include mechanical, biologic, organic, fluid, etc. components. At times, even HI devices (e.g., chiplets or SiPs) may themselves be integrated as a component in a different HI device. Therefore, using HI technology in SOMs, SiPs, and chiplets can provide components or systems that are otherwise impossible or impractical to integrate in a single silicon circuit such as an ASIC or SoC. Other discrete circuits that may be included in an HI device are, for example, non-silicon-based circuits, such as germanium, Gallium Nitride (GAN), or organic-based components. HI devices are also attractive because they may allow for miniaturization of a complete system in a single package. HI devices may include mechanical devices. One example is a mechanical energy source using vibration or heat to create energy (e.g. a self-winding watch concept). In some instances, HI devices may also reduce a microelectronic system on a printed circuit board (which may be tens of square cm in size) to a single package of a square cm or less.

As a result of this seemingly unlimited ability to integrate more electrical/mechanical components into one package, new issues of cost-effective manufacturing processes are becoming a reality. These issues may include the cost of the substrate due to its greater complexity, the inability to use well-understood encapsulation methods, and the attachment of the external connectors to the device package. Attempts have been made to address these issues, with the most successful being to remove the good substrates from a strip or panel of multiple substrates and process them one at a time rather than as a strip or panel of multiple substrates. This is inefficient.

Aspects of the present disclosure focus on solving one or more existing issues, both in time and cost. One or more embodiments are directed to an apparatus in the form of a Substrate Carrier Frame (SCF). By populating SCFs with Good Singulated Substrates (GSSs), the production process flow aligns with the already existing production process. The use of SCFs can have a significant impact during the encapsulation and external connector attachment processes by enabling batch processes.

Today, systems are typically designed starting with various components which are used to implement a desired circuit, one subsystem at a time. This process is unique for each design, which takes additional design resources, extending the development timeline, and increasing development risk. Systems using processors and programmable logic devices offer an exceptionally flexible solution that may be customized through programming for a desired system or end use. Often, these processors and devices need a set of support components to build a complete system. Such support components are, for example, DDR and FLASH memories, power supplies, PHY interfaces, wireless modules, security devices, other active devices, and (potentially) hundreds of passive devices and components.

As these systems become more complex with more components for higher performance and increased internal and external interconnect requirements, the substrates on which the components are attached and electrically interconnected become more complex and the present methods of assembly may become inadequate. One source of issues is the substrate complexity.

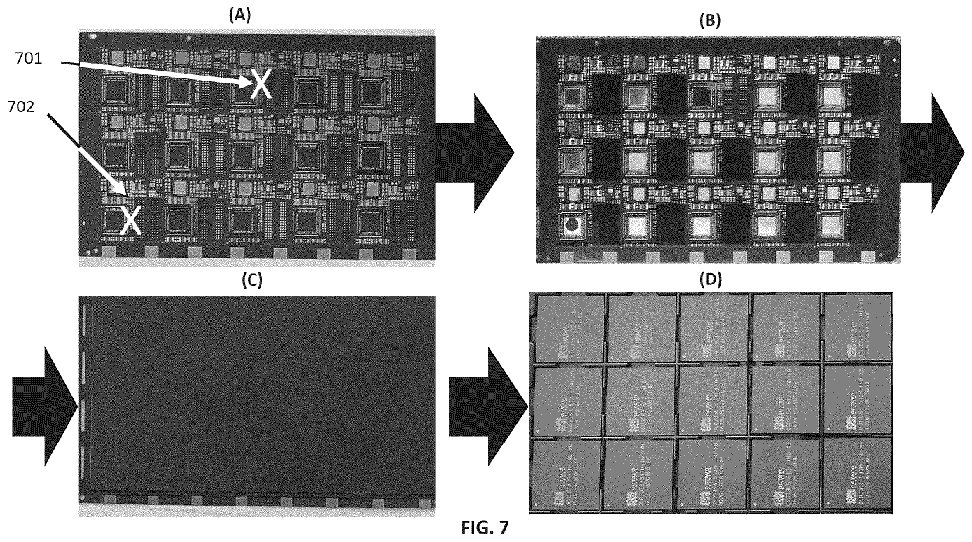

A traditional assembly flow for a panel or strip of substrates for complex heterogeneous integrated circuits is for each substrate in the panel or strip to first be tested. The substrates that test good in the panel or strip are then populated with the electronic components needed to make up the integrated circuit, component, device or other circuit element. Here, the “strip” or “panel” includes multiple substrates, and picture of a strip of substrates for a SiP is shown in FIG. 7 at (A). Next, then the entire panel or strip of populated substrates is encapsulated or molded. Then external connectors are added to the good populated and encapsulated substrates to complete the circuit. Then the circuit is singulated by cutting it out of the panel or strip, and then it is tested. With this process, the resulting yield of the complex substrates is significantly reduced, making it impractical and not cost effective to process the substrates in panel or strip form with multiple substrates per panel or strip. One aspect that impacts the yield of the substrates is the number of trace (and/or pour) layers needed, and the tight design layout rules of each layer. Currently, in complex HI designs, the good substrates are cut out of the strips and go through the manufacturing process one device at a time. Even though the substrates may be assembled one at a time, it is still acceptable to continue some of the traditional process steps. But certain traditional process steps are not suited for “one at a time” processing. These steps include encapsulation and ball attach (the attachment of external connectors). The result of not being able to encapsulate the device results in needing to replace the encapsulant with a lid or covering. Attaching a lid or covering to component is not only far more expensive and time consuming than encapsulating the device, but it also has long term reliability issues and potentially requires larger substrates.

In more detail, as systems become more complex and require more components, the system substrate requires more conductive layers and tighter design rules. This increase in layers allows for more defects, resulting in a strip of substrates having an increasing number of substrates in a panel testing bad. If enough substrates in the panel test bad, then the remaining good substrates are cut out (“singulated”) of the panel. These individual singulated substrates may then be further processed individually.

However, the manufacturing equipment used to place components on a substrate may be programmed to only place components on the good substrates in a panel. In this manner each good substrate (even in a panel) may be populated with its system components and they are properly interconnected to functionally operate. However, the bad substrates that remain in the panel are not populated with components.

Once the good substrates are populated with their components, whether in a strip or singulated, then the substrate and associated components in a panel are typically encapsulated. A picture of populated substrates including a few “bad” substrates 701, 702 of FIG. 7, is illustrated in FIG. 7 at (B). If the encapsulation includes the bad substrates, then the encapsulated panel includes bad substrates that have also been encapsulated. FIG. 7 at (C) illustrates an encapsulated panel of SiP devices like those in the previous pictures (A and B). The encapsulated good substrates may then be “singulated”, i.e. be cut out of the panel, for further processing steps, like attaching external connectors (e.g. balls), or the encapsulated devices may be singulated after the external connectors are attached to the devices. Following the external connector attachment, the good, encapsulated devices may be singulated, i.e. cut out of the strip. FIG. 7 at (D) illustrates the SiP devices that have been singulated. Then, the remaining portion of the strip is discarded. This discarded portion increases the overall processing cost and decreases the yield, especially if the entire strip has been encapsulated, as the encapsulant and its expense is wasted.

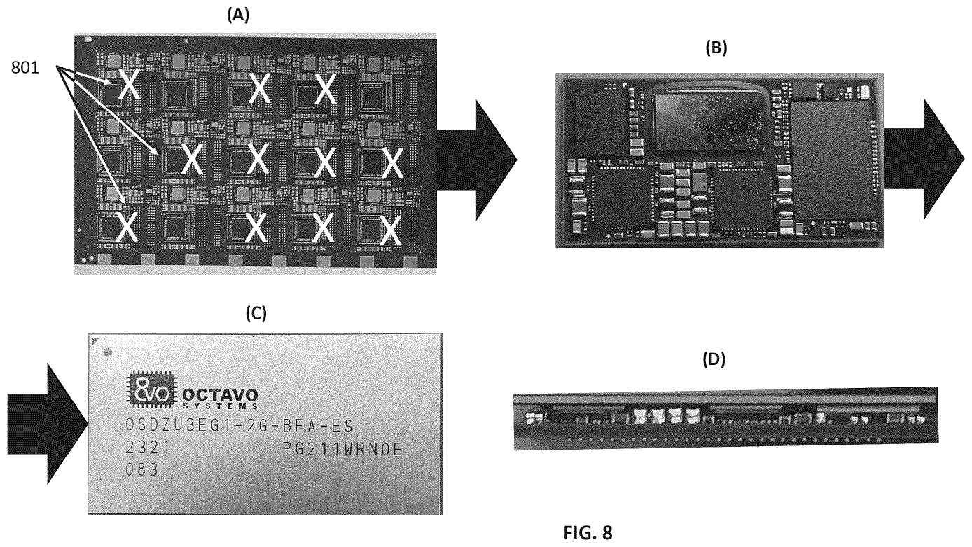

One way to avoid the extra processing costs is to not encapsulate the bad substrates in the panel. FIG. 8 illustrates a panel of substrates where the electrically bad substrates 801 are “Xd” out. That is, the good substrates are singulated, i.e. cut out of the panel, and only the good substrates may be then individually populated with components, somehow encapsulated and then individually provided with external connectors. However, this means that good substrates are individually encapsulated and then individually provided with external connectors. This again results in increased processing costs and time since only one substrate is dealt with at a time, rather than a “batch mode” process for the multiple substrates in a panel. Further the batch mode process for encapsulating may only be done using strips of substrates making it impractical, if not impossible, to encapsulate the singulated devices. Therefore, the devices are finished with lids rather than encapsulation. FIG. 8 (B-D) illustrate, respectively, a lid-less, a top lidded, and a side view of a SiP device using a lid, rather than encapsulant.

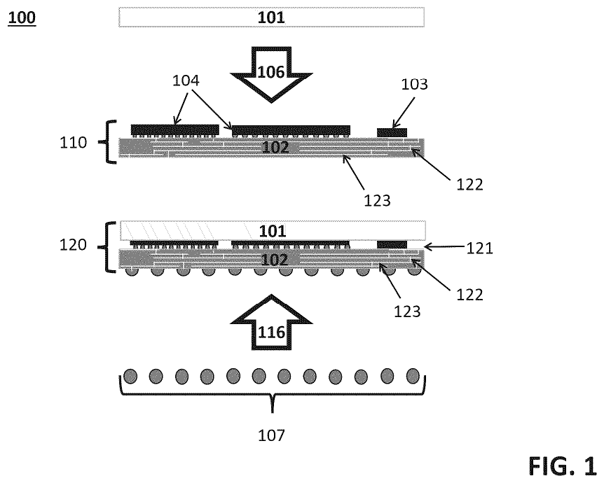

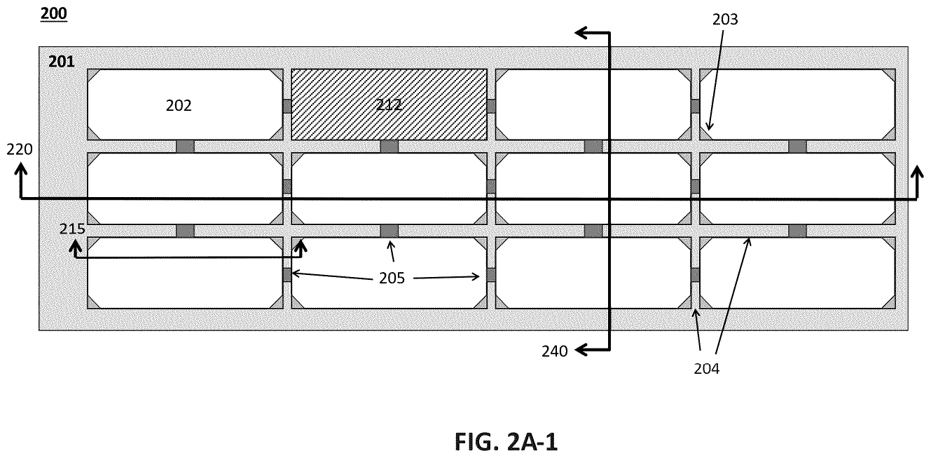

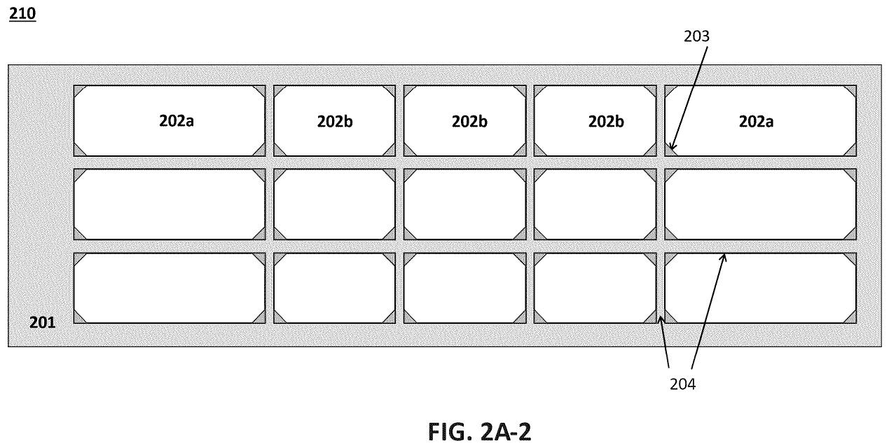

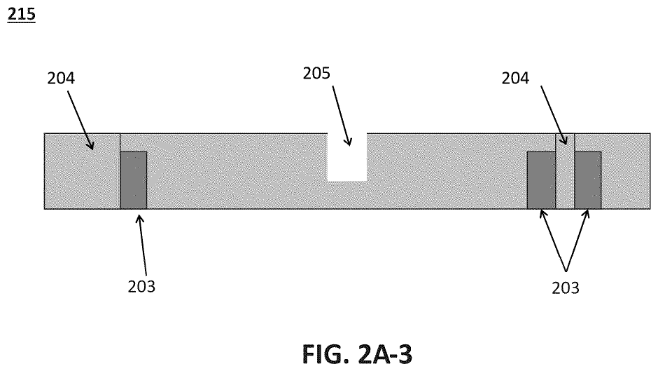

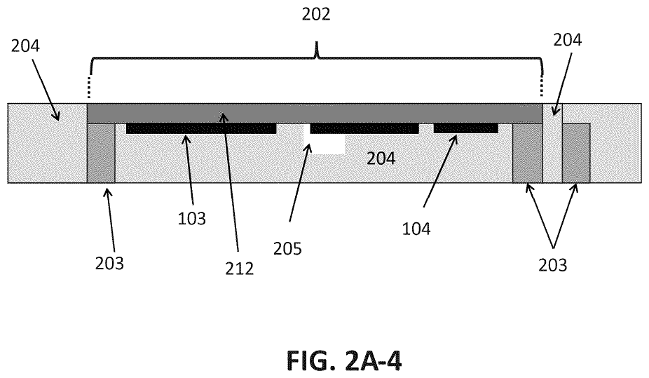

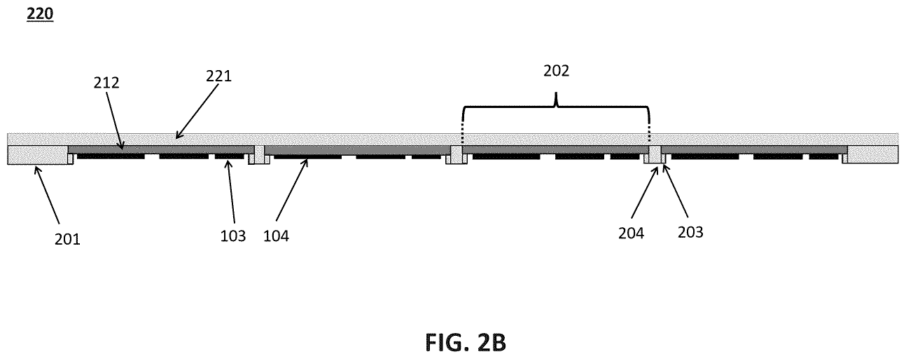

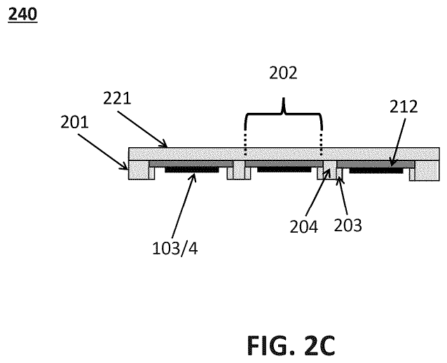

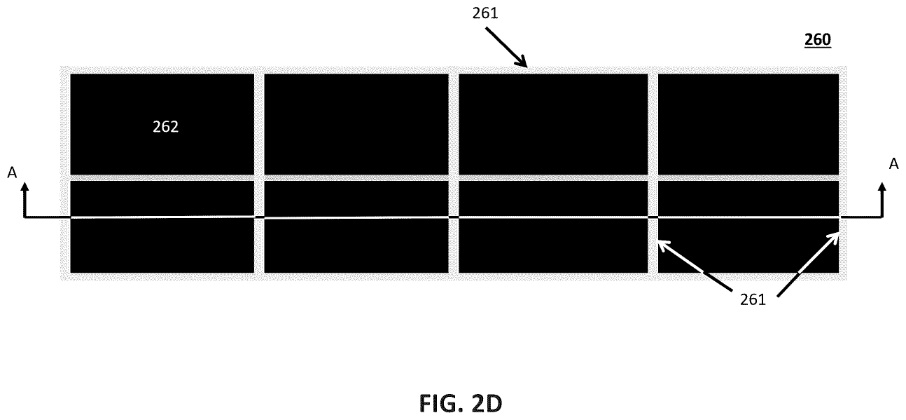

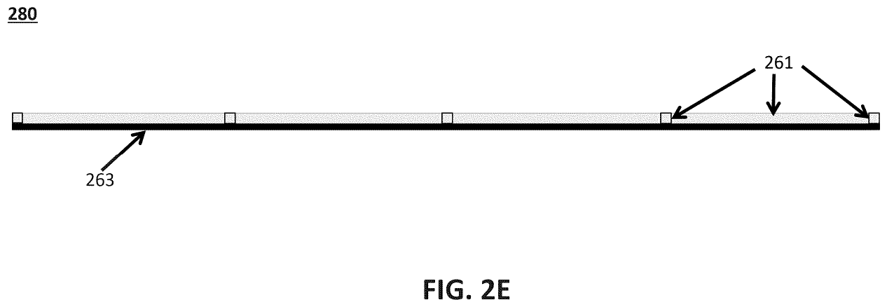

Referring now to FIG. 1, a method 100 for packaging a Heterogeneous Integrated Device (HID) having a singulated substrate is illustrated. In this example, an assembled substrate 110 is used, which comprises a multi-layer substrate 102 where each layer has conductive traces 123 and the layers interconnected with vias 122. On the substrate, multiple components 103, 104 are attached and operatively interconnected. That is, the substrate is “populated” with its components necessary for operation. For ease of depiction purposes, in the following figures (e.g., FIGS. 2-5), the substrates will be shown without conductive elements 123 and vias 122 depicted and identified. Also, for ease of depiction purposes, the number of components illustrated in FIG. 1 and other later figures are reduced from the actual number of components that may be found tightly and densely packed in actual devices (see, e.g., FIG. 8 at (B)).

Not all substrates in a panel are defect free when tested, often resulting in a low yield of substrates 102 in a strip or panel of substrates. This may be, for instance, due to the complexity of a multilayer design and tight layout geometries for lines in the same layer. Rather than assembling substrates in a strip made up of multiple substrates, the useable (tested good) substrates 102 may be cut from (singulated) the strip due to a low yield of multiple substrates in a strip and each singulated substrate is processed individually. As a result, lids 101 may be used in the assembly process for singulated substrates, rather than encapsulant. In the example of FIG. 1, the lid 101 on each device is secured in step 106 to the components 103, 104 (and substrate 102) with adhesive. In order to secure the lid 101 to the substrate, the substrate is made slightly larger (e.g., 5 mm in each of the x- and y-dimensions) to give the lid adequate area to which it may attach. When the size of the substrate needs to be minimized, the lid 101 is secured to the components 103, 104 rather than a substrate allowing for a smaller sized footprint for a SiP. In this example, after the lid is attached, external connection balls 107 may be attached, as depicted by step 116, to the substrate 102. However, a process may have increased costs when assembling singulated devices using lids, rather than strips of multiple substrates using a batch molding encapsulating process, leaving gaps 121 between the substrate and lid exposing components 103, 104.

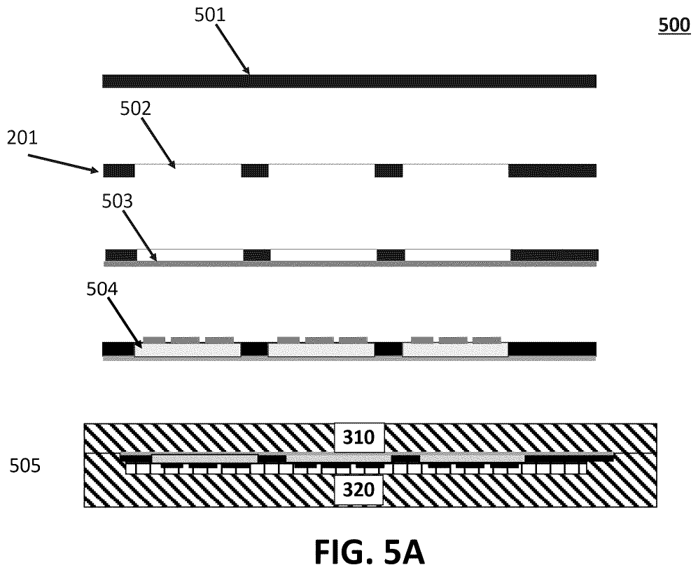

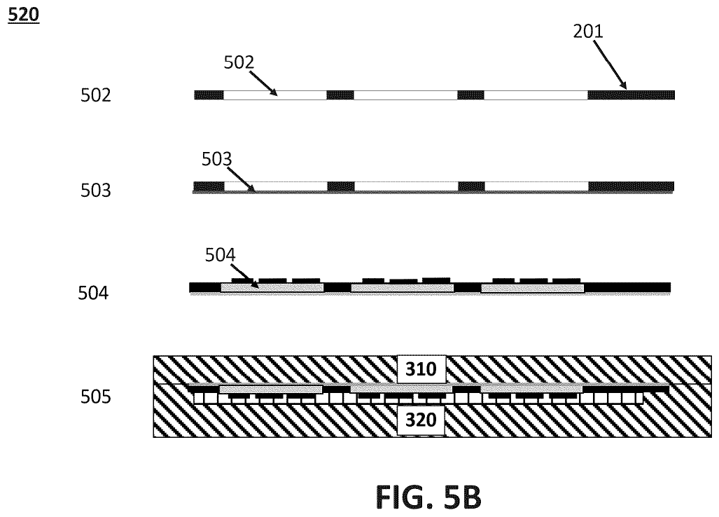

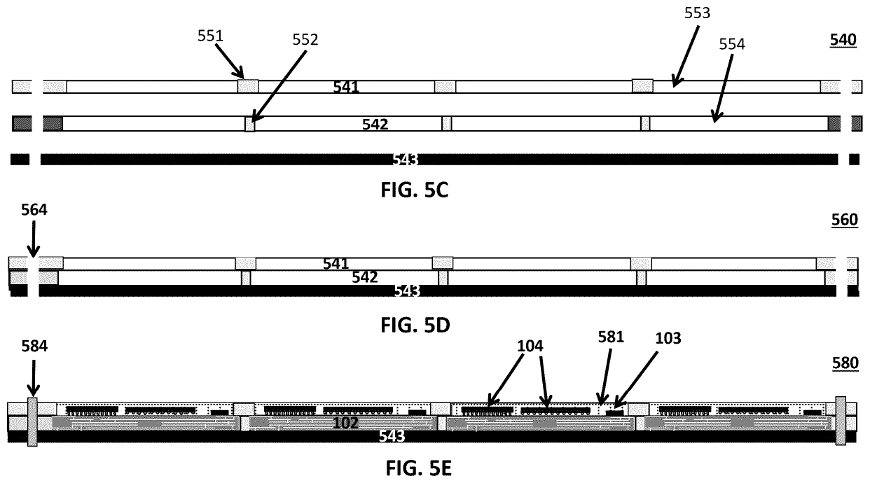

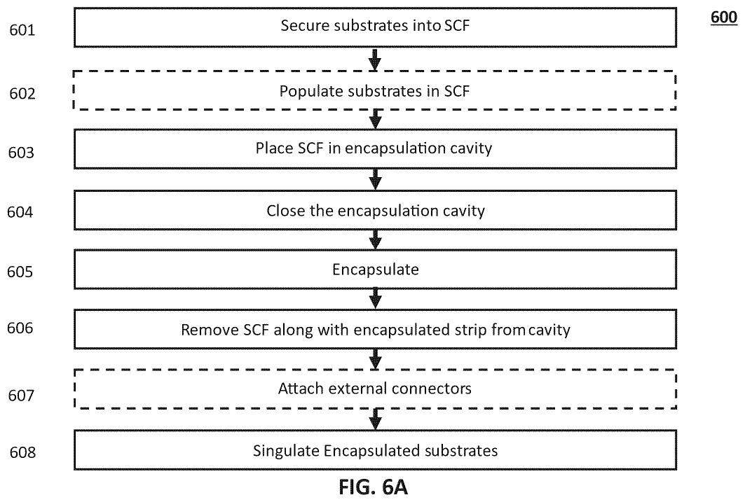

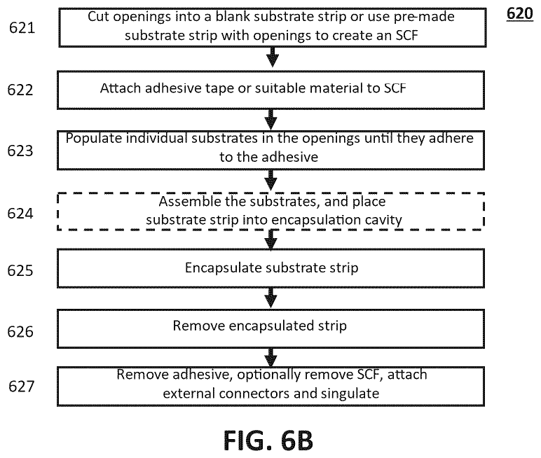

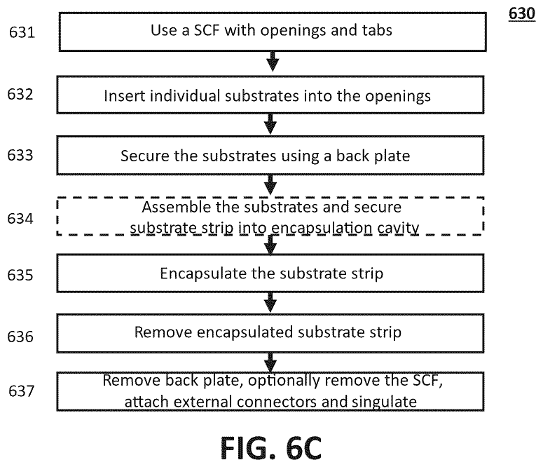

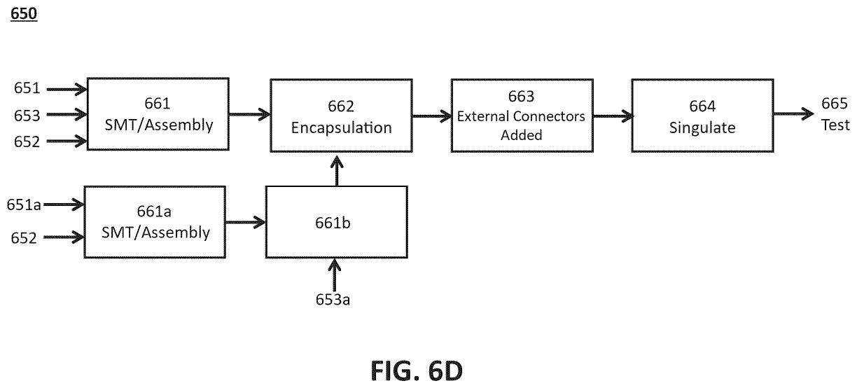

According to embodiments, methods and devices are provided for batch molding (encapsulating) singulated substrates. In some embodiments, a 1-piece substrate carrier frame (SCF) is used for batch molding singulated substrates (e.g., in a transfer mold). This is illustrated in FIGS. 2D, 2E, 4A, 4B, 4C, 4D, 4E, 4F, 6A, and 6B. In certain aspects, the SCF may be reusable, and it may be formed of metal. In some embodiments, batch molding of singulated substrates is performed using a disposable 1-piece substrate carrier frame (SCF), either in compression mold or transfer mold (e.g., inverted strip). This is illustrated in FIGS. 5A, 5B, and 6C. In certain aspects, it may be formed of plastic. In other embodiments, a 2-piece reusable substrate carrier frame (SCF) is used for batch molding singulated substrates. This may use, for instance, a compression mold (e.g., inverted strip). Aspects of the second embodiment are illustrated in FIGS. 2A, 2B, 2C, 3A, 3B, 3C, 3D, 3E, 3F, and 6D. In embodiments, the 2-piece SCF is formed of metal. Some embodiments may use a 3-piece substrate carrier frame (TSCF), such as illustrated with respect to FIGS. 5C, 5D, and 5E.

FIGS. 2A-1 and 2A-2 depict a top view of an empty substrate carrier frame (SCF) of embodiments, while FIGS. 2A-3 and 2A-4 show certain details of the SCF. FIGS. 2B and 2C depict a side view and an end view, respectively, of a populated substrate carrier frame (SCF) populated with substrates and ready for component assembly, encapsulation, and external connector attachment. The singulated substrates may be inserted into the SCF either prior to component assembly or before encapsulation. In certain aspects, the SCF is populated with substrates with components attached ready for encapsulation and attachment of external connectors.

Referring now to FIG. 2A-1, an arrangement 200 using a substrate carrier frame (SCF) 201 is provided according to some embodiments. In this example, the SCF 201 comprises ribs 204 spaced appropriately apart to create substrate nesting openings (SNOs) 202 sized to accept singulated substrates 212 (e.g., as illustrated in FIGS. 2B and 2C). According to embodiments, the openings (SNOs) 202 have four retainer tabs 203, each tab in one of the four corners of the nesting opening 202 to hold the substrates 212 in place. One substrate 212 is shown (in hash) as an example in FIG. 2A-1, though in practice, more than one (e.g., all) of the SNOs 202 may contain substrates 212. Also, though shown with four corner retainer tabs 203 in this example, other numbers of tabs and other placements (e.g., along the edges of SNOs 202) may be used in other embodiments. In some embodiments, and as shown in FIGS. 2A-3 and 2A-4, mold channels 205 can be placed in the ribs 204 of the SCF 201 so that mold compound (encapsulate) can flow between the openings and connect all substrates together for batch/strip processing in the case where the SCF 201 is removed. In other embodiments the mold channels 205 are removed which allows individually molded devices to be removed from the SCF 201 and processed. Mold channels may be optional.

In certain aspects, the thickness of the substrate carrier, or the retainer tabs, can provide the desired thickness of encapsulate to cover the components on the substrate to a desired thickness. That is, the height of the location of the tabs in an opening along the side of a rib is adjusted, depending on the thickness of the substrate and the height of the components on the substrate to be installed on the substrate and the desired thickness of encapsulant over the components in the packaged device. In other embodiments the tabs may be removed or replaced with other methods for retaining the substrates in the SCF. In addition, a substrate carrier frame (SCF) 201 may be reusable or disposable. In some embodiments, depending on the thickness of the various features, the encapsulant may cover the tabs 203 depending on how the strip is cut apart into individual devices.

FIG. 2A-2 depicts an arrangement 210 of substrate carrier frame (SCF) 201 where the openings SNOs 202 in the same substrate carrier frame (SCF) 201 are different sizes for different sized singulated substrates, but the construction can be the same as FIG. 2A-1. As noted elsewhere, in addition, the substrate carrier frame (SCF) 201 may be reusable or disposable, including when provided with different sized nesting cavities as shown in FIG. 2A-2. In certain aspects, arrangement 210 depicts an embodiment of a substrate carrier frame (SCF) 201 where ribs 204 are spaced appropriately apart to create nesting cavities 202a, 202b to accept different sized, singulated substrates 212 (for instance, as described with respect to FIGS. 2B and 2C). In this embodiment, the different sized nesting cavities 202a, 202b have four retainer tabs 203, each in one of the four corners of the nesting cavities 202 to hold the substrates 212 in place. In other embodiments the retainer tabs 203 may be removed or replaced with other methods of retaining the substrates in the SCF. Likewise, different numbers and placements of tabs may be used. As in FIG. 2A-1, notches 205 (in the ribs 204) may be inserted to improve the flow of the encapsulant.

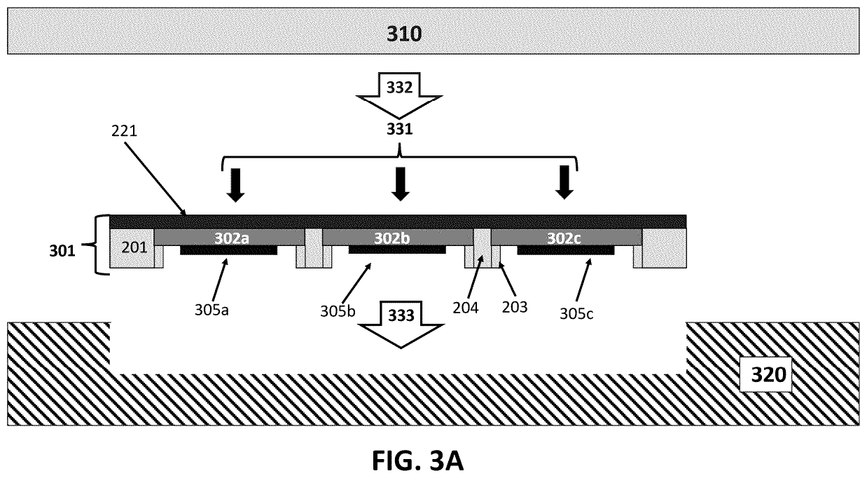

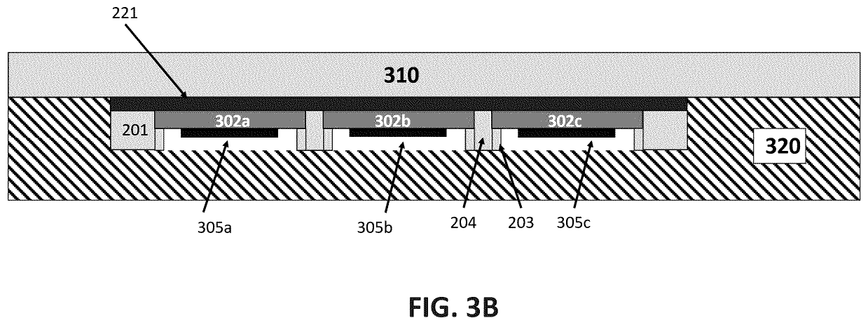

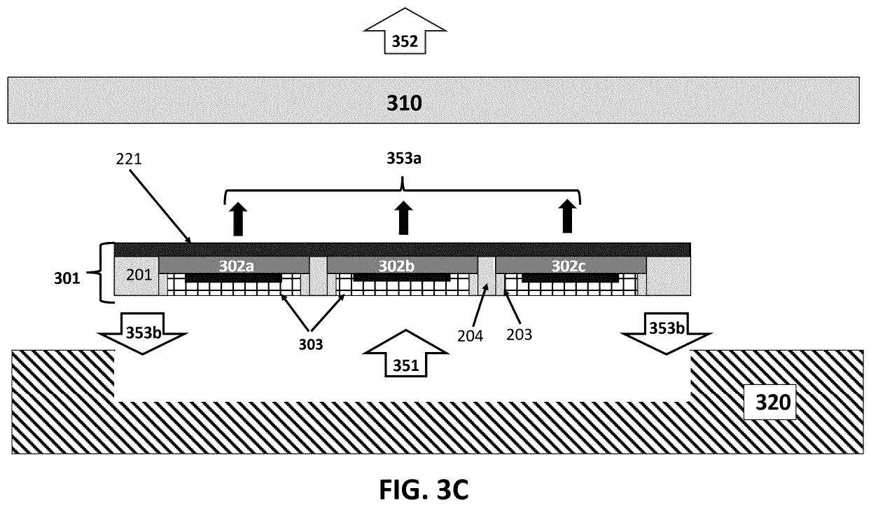

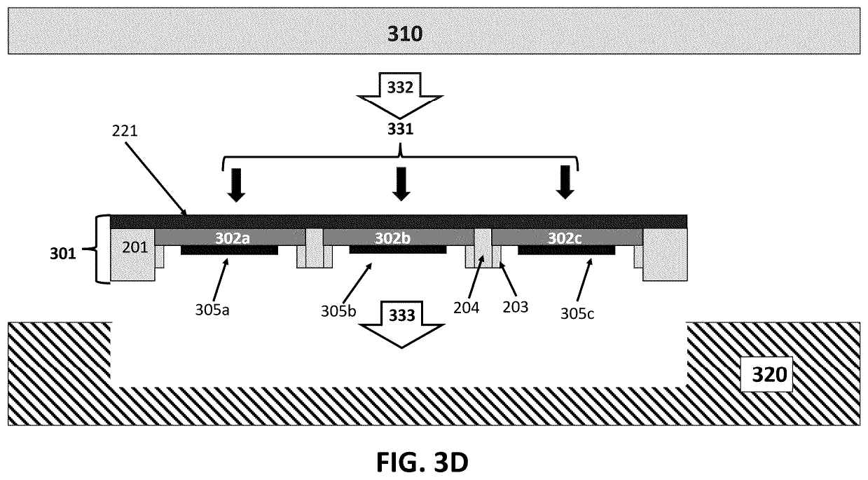

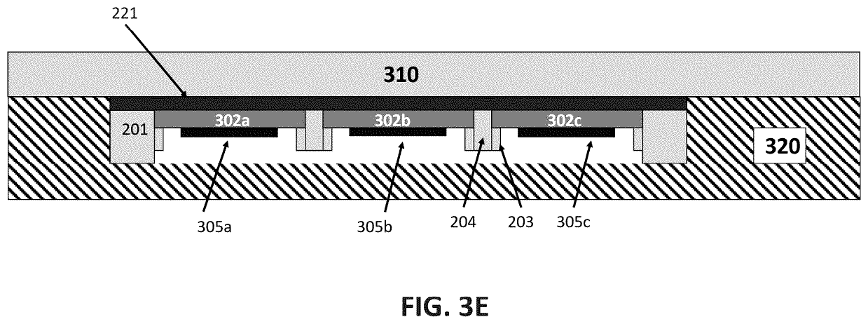

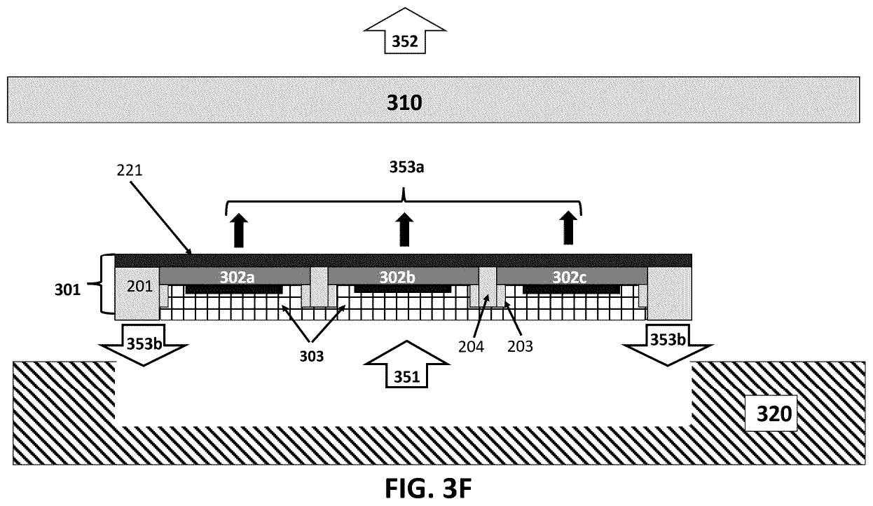

Referring now to FIGS. 2A-3 and 2A-4, detailed views of a tray rib are provided in accordance with some embodiments. In the example of FIG. 2A-3, one of the ribs 204 has a notch 205. In this embodiment, the notch 205 is centered between two tabs 203; however, other placements may be used. And depending on the desired result, one or more notches may be inserted in each rib 204 of each nesting cavity 202. In FIG. 2A-4, a side view of a nesting cavity 202 with a notch 205 in a rib 204 and a substrate 212 populated with components 103, 104 is shown.

According to some embodiments, FIG. 2B depicts a side view of the substrate carrier frame (SCF) 201 after the substrates have been populated with components 103, 104 and are ready for encapsulation. The populated substrates 212 are placed in the SNCs 202 in the substrate carrier frame (SCF) 201 and held in place by the ribs 204 of the SCF 201. Each rib 204 in this example has a tab 203 in each corner of the substrate nesting cavity 202 of the SCF where each substrate 212 is placed. Substrates 212 are secured in frame 201 by a backplate 221 removably attached to the SCF 201 to keep the substrates 212 secure.

FIG. 2C depicts an end view of the substrate carrier frame (SCF) 201 having substrates 212 each having been populated with components 103, 104 and ready for encapsulation, as described in connection with FIG. 2B. The populated substrates 212 are placed in frame 201 and held in place by the ribs 204 of frame 201. Each rib 204 has a tab 203 in each corner of the nesting cavity 202 of the frame where each substrate 212 is placed. Substrates 212 are secured in frame 201 by backplate 221, which is removably attached to frame 201. Backplate 221 may be any suitable material with a polished or non-sticky surface for the encapsulant and may be reusable or disposable.

Again, the substrates may be populated with components before or after placing a good substrate in in the SCF.

FIG. 2D depicts a one-piece substrate carrier frame 260 according to embodiments. In this example, the SCF 260 can use an attached bottom plate 263 and substrate nesting cavities (SNC) 262 to secure the individual substrates. Ribs 261 on the substrate carrier frame form substrate nesting cavities which constrain the individual substrates (e.g., to keep them from getting mis-aligned). As with other embodiments, the cavities (SNCs) 262 in the same substrate carrier frame (SCF) 260 may be different sizes for different sized substrates. Bottom plate 263 may be, for example, any suitable material with a polished or non-sticky surface for the encapsulant. However, other materials may be used. In addition, the substrate carrier frame (SCF) 260 may be reusable or disposable. FIG. 2E is a side view 280 along cross-section A-A. Specifically, FIG. 2E depicts the side view 280 of a one-piece substrate carrier tray of FIG. 2B with nesting cavities 262 with a bottom plate 263 to hold individual substrates. Ribs 261 on the substrate carrier plate form nesting cavities which constrain the individual substrates from getting mis-aligned. The bottom plate 263 may be made of, but not limited to, metal, plastic, or adhesive tape.

One or more aspects of the disclosure provide devices for encapsulating a plurality of singulated substrates, where the device comprises a frame structure with a plurality of openings therein and in some instances, alignment pins/holes for use with semiconductor processing equipment, wherein each opening is sized to contain a singulated substrate and having a size comparable to a conventional panel of substrates.

Referring now to FIGS. 3A, 3B, and 3C, one or more steps are illustrated for insertion and removal of a substrate frame carrier 301 into mold cavity 320 for encapsulating singulated substrates. According to embodiments, the steps illustrated in these figures may be used with a SCF 201 according to FIGS. 2A, 2B, 2C. And in this embodiment, the SCF used may be either reusable or disposable, and in certain aspects, the molding may be compression molding.

FIG. 3A depicts the steps for loading of the populated substrate carrier frame (PSCF) 301 into the mold cavity 320 according to embodiments. The first step 331 is to load the singulated substrates 302a, 302b, 302c into a substrate carrier frame, such as SCF 201. For ease of depiction purposes, loaded substrate carrier frame assembly 301 contains substrate carrier frame 201 loaded with only three substrates 302a, 302b, 302c with attached representative components 305a, 305b, 305c (“populated”). Once the SFC 201 (or other SCF) has been loaded in step 331 with the singulated substrates 302, the backplate 221 is attached in step 332 to the loaded substrate carrier frame 301. Finally, the assembly 301 consisting of the loaded SCF 301 and mold top plate 310 is placed in the mold cavity 320 in step 333 and then encapsulated. In some embodiments the height of the carrier frame ribs 204 and the tabs 203 are the same, thereby limiting the thickness of the encapsulant by the tab 203. Other thicknesses may be used.

FIG. 3B depicts the loaded substrate carrier frame assembly 301 in mold cavity 320, but not yet encapsulated. The loaded substrate carrier frame assembly 301 includes the substrate carrier frame 201 with devices 302a,b,c. It is held in place by the back plate 221 and mold top plate 310 and ready for mold compound. According to embodiments, at this stage the mold compound 303 has not yet been injected.

FIG. 3C depicts one or more steps for removing 351 the molded/encapsulated devices 302 from mold 320. First the mold top plate 310 and loaded substrate carrier frame assembly 301 are removed in step 351 from the mold 320. Once removed, the mold top plate 310 and backplate 221 are removed in steps 352, 353a, respectively, from the loaded substrate carrier frame assembly 301. In the case of a reusable SCF, the encapsulated devices 302a, 302b, 302c are then removed in step 353 from the loaded substrate carrier frame assembly 301. Finally, the substrate carrier frame may be reused after any excess mold compound 303 is removed in steps 353a and 353b. In the case of a disposable SCF, the encapsulated devices 302 are not removed and the entire loaded substrate carrier frame assembly 301 proceeds to the next step in assembly (e.g., for singulation). For either the reusable or disposable SCF, when dictated by the assembly process, the encapsulated devices 302 may then be singulated/separated and further processed. Because of the SCF and the encapsulated substrates, this arrangement is now equivalent to a normal panel of good substrates that have been encapsulated, and accordingly may be treated as such for future processing steps.

FIGS. 3D, 3E, and 3F depict similar processes as FIGS. 3A, 3B, and 3C. However, in these figures, the SCF 201 is not a uniform height, which allows for a thicker encapsulant 303. Additionally, this allows the encapsulant to connect all the substrates together for strip/batch processing in future process steps. In this respect, even without a disposable frame, all of the devices 302 may be removed and processed as a single unit, like a panel. In some embodiments, FIGS. 3D, 3E, and 3F depict the insertion and removal of the loaded substrate carrier frame (LSCF) 301 into a compression mold cavity 320.

In FIG. 3D, the first step is to load the singulated substrates 302a, 302b, 302c into the substrate carrier frame 201. Note, in this depiction the loaded substrate carrier frame (LSCF) 301 has the substrate carrier frame 201 loaded with three substrates 320 with attached components 305. Once the SCF 201 has been loaded in step 331 with singulated substrates 302, the backplate 221 is attached 331 to the loaded substrate carrier frame assembly 301. Finally, the assembly of the LSCF 301 and upper mold cover 310 are placed in the mold cavity 320. In this embodiment, the height of the SCF 201 is greater than the ribs 204 and the tabs 203 allowing the thickness of the encapsulant to be determined by the SCF 201. FIG. 3E depicts the loaded substrate carrier frame 301 inserted into the mold cavity 310, 320. LSCF 301 is held in place by the backplate 221 ready for mold compound. At this stage of the example, the mold compound 303 has not yet been injected. FIG. 3F depicts the removal process of the devices 302 with mold compound 303 from the mold block 310, 320. First the top mold cover 310 is removed 352, and the substrate carrier frame assembly 301 is removed 351 from the mold block 320. Once removed from the mold, the backplate 221 is removed 353a from the substrate carrier frame assembly 301. In embodiments, where the encapsulated populated substrates 302 are captured within the SCF, they will need to be singulated (e.g., cut out of the LSCF). In some embodiments, a ball attach process, such as described with respect to FIG. 6C, may precede the removal of the populated substrates from the SCF.

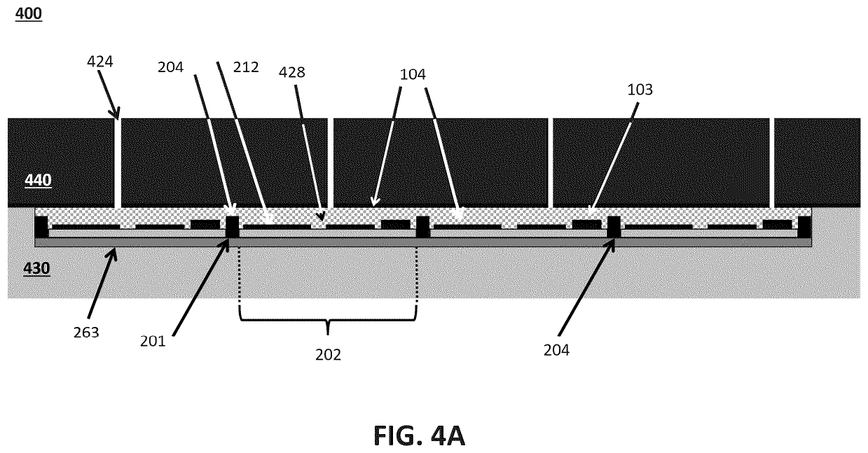

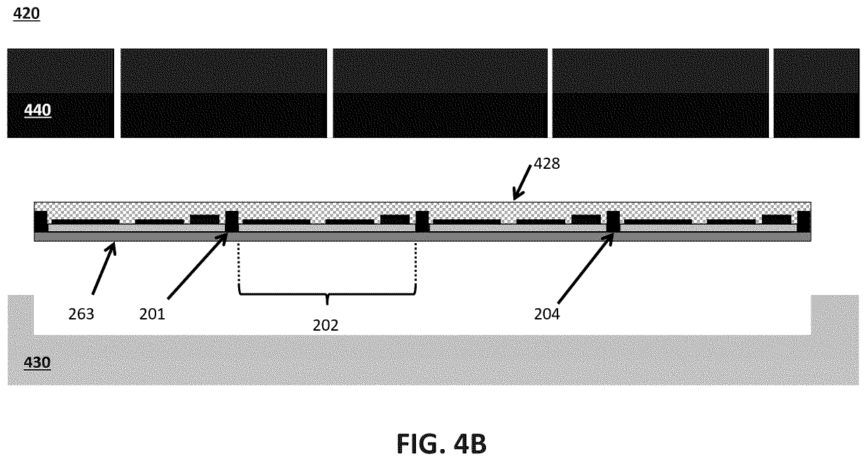

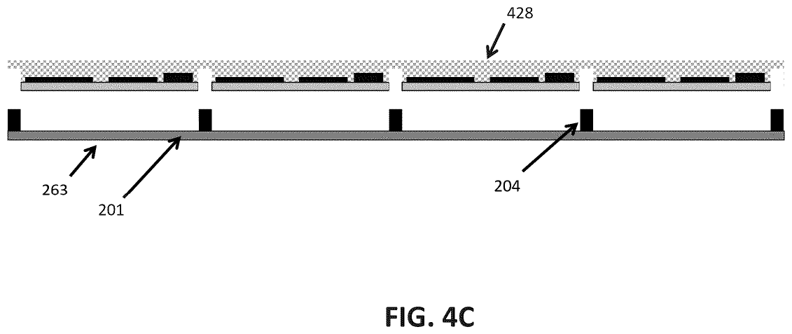

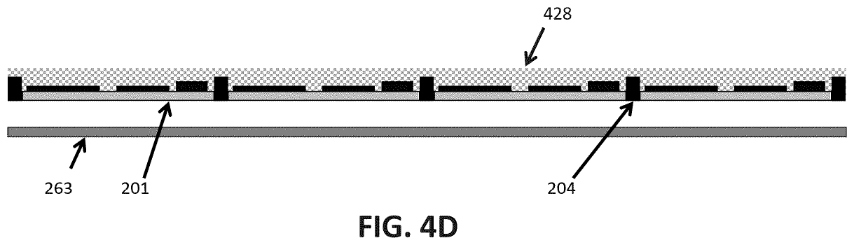

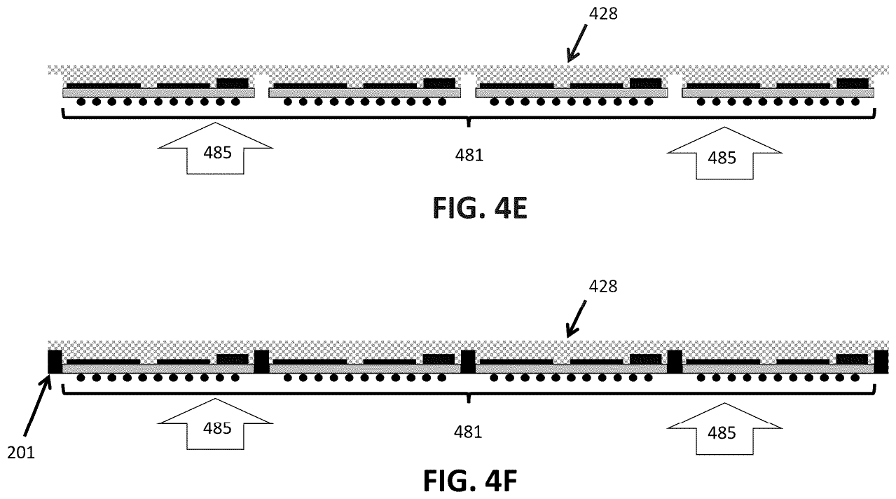

FIGS. 4A, 4B, 4C, 4D, 4E, and 4F depict the steps for encapsulation of a populated substrate carrier frame (SCF) using a transfer mold and followed by attaching external connectors to the populated substrates, while still in a “panel” or “strip” format. This embodiment of the SCF may be either reusable or disposable. According to some embodiments, the steps illustrated with respect to FIG. 4 may be used with an SCF 260 as described in connection with FIGS. 2D and 2E.

FIG. 4A depicts a side view 400 of the substrate carrier frame (SCF) 201 in transfer mold 430, 440 after encapsulation. The substrates 212 have been populated with components 103, 104 and are encapsulated 428. The populated substrates 212 are placed in the substrate nesting cavities 202 in the substrate carrier frame (SCF) 201 and held in place by the SCF 201. In certain aspect's, each rib 204 (see FIGS. 2A, 2B and 2C) in this embodiment does not have a tab in each corner of the nesting cavity 202 of the SCF where each substrate 212 is placed. In this example, the substrates 212 are held in the frame 201 without tabs. The molding injection port is 424. Again, the cavity depth may be adjusted to provide the desired encapsulant thickness layer over the components 103, 104.

FIG. 4B depicts a side view 420 with top mold cavity 440 and bottom cavity 430 opened and the encapsulated strip 428 in substrate carrier frame (SCF) 201. This figure depicts encapsulated, singulated substrates mounted in a SCF. In more detail, the mold 430,440 has been opened and the “panel” of now encapsulated, singulated substrates removed from the mold. Because of the SCF and the molding plastic encapsulating the substrates, this arrangement is now equivalent to a normal panel of good substrates that have been encapsulated, and accordingly may be treated in as such for future processing steps.

FIGS. 4C and 4D depict a side view of a reusable SCF (FIG. 4C) and a disposable SCF (FIG. 4D) where the molded substrates strip 428 is removed from the substrate carrier frame (SCF) 201.

FIG. 4C depicts a side view of panel of the molded substrates 428 removed from a reusable substrate carrier frame (SCF) 201. In more detail, the SCF is removed from the singulated substrates that are now rigidly held together by the mold the exists between the substrates. Again, this form is basically a “panel” equivalent to a normal panel of good substrates that have been encapsulated and accordingly may be treated in as such for future processing steps. Alternatively, for a disposable substrate carrier frame (SCF) 201, the SCF is not removed from the “panel” of encapsulated, singulated substrates and is used accordingly for future processing steps. In some embodiments, an SCF may become a part of the final packaged device.

FIG. 4D depicts a side view of panel of the molded substrates 428 removed from the substrate carrier frame (SCF) 201. Only the backing material 263 is removed from the singulated substrates that are now rigidly held together by the mold and the disposable SCF 201. Again, this form is basically a “panel” equivalent to a normal panel of good substrates that have been encapsulated and accordingly may be treated in as such for future processing steps.

FIGS. 4E and 4F depict a side view molded strip 428 for external connector attach 485 prior to singulation. The difference is if the SCF 201 is removed as in FIG. 4E in the case of a reusable SCF or retained as in FIG. 4F in the case of a disposable SCF. In more detail, the molded strip of encapsulated substrates is processed in a manner to attach external connectors to the base of each of the substrates, using existing techniques that are well known in the art.

FIGS. 5A, and B depict an embodiment using alternative steps 500, 520 that can be applied when using a disposable one-piece substrate carrier frame 201 to process singulated substrates.

FIG. 5A depicts process 500 that starts with a disposable one-piece substrate carrier frame 201 in some embodiments. The disposable one-piece substrate carrier frame 201 could have been manufactured with openings for singulated substrates or modified after manufacture. Alternatively, openings 502 for containing a singulated substrate may be cut into a blank strip 501 to create a SCF. The SCF 201 then has adhesive tape or some other suitable backing material 503 applied to the back of the SCF 201, with the adhesive side facing up such that it is secured to the SCF 201. Once the SCF 201 is prepared, the substrates 504 (which may be populated or not) are inserted into the openings 502 of the SCF 201. The newly created strip can then be assembled and encapsulated 505 using conventional assembly and encapsulating processes.

FIG. 5B depicts a process 520, which starts with a reusable substrate carrier frame 201 with openings 502 pre-cut into the substrate carrier frame 201. Once the SCF 201 is obtained, an adhesive tape or some other suitable backing material 503 is applied to the back of the SCF 201, with the adhesive side facing up such that it is secured to the SCF 201. In some embodiments, the SCF 201 may be made of metal. Once the SCF 201 is prepared, the substrates 504 (which may be populated or not) are inserted into the SCF 201. The newly created strip can then be assembled and encapsulated 505 using conventional assembly and encapsulating processes.

FIGS. 5C, 5D, and 5E depict aspects of a three-piece substrate carrier frame (TSCF) according to some embodiments. Referring now to FIG. 5C, view 540 shows the three components 541, 542, and 543 of the TSCF separated. FIG. 5D shows the three components assembled 560 and unpopulated. FIG. 5E shows a view 580, with the TSCF populated with substrates 102 and components 103,104 and encapsulant 581. The three components of the TSCF are: the top plate 541, the SCF 542, and the bottom plate 543. The tabs 551 are in the top plate, and the SCF ribs 552 are in the SCF 542. The openings in the top plate 553 and SCF 554, along with the back plate 543, are used to secure the substrates in the TSCF. The three components of the TSCF are aligned and secured together with alignment pins 584 through the alignment holes 564 in each of the components.

FIGS. 6A, 6B, 6C, and 6D depict methods according to embodiments. The methods may be, for instance, for manufacturing complex devices whose substrates have been singulated and are processed using a substrate carrier frame (SCF). According to embodiments, the methods may use the SCFs described above with respect to FIGS. 2-5.

FIG. 6A depicts a process 600 according to embodiments. In some embodiments, the process 600 may begin with securing (601) individual substrates into the substrate carrier frame (SCF), which could be disposable or reusable. Next, in step 602 (which may be optional in some embodiments), the substrates are populated. This could include, for instance, populating the substrates with components. Alternatively, pre-assembled substrates could have been placed into the substrate carrier frame 601. Then the SCF containing assembled substrates is placed 603 in the encapsulation cavity, and the encapsulation cavity is closed 604. Next, the assembly is encapsulated 605. This could include, for instance, transfer molding. The encapsulated body is then removed 606 from encapsulation cavity and the substrate carrier frame (SCF) can be optionally detached from the encapsulated devices. External connectors are added 607 which could include, but are not limited to BGA balls, pins, or nothing. In some embodiments, this may be optional. In some embodiments, the external connectors may be added while the substrates remain in the SCF. Finally, the encapsulated substrates (now packaged devices) are singulated 608.

FIG. 6B depicts a process 620 according to embodiments. In certain aspects, process 620 may be an alternative or additional method where the substrate carrier frame is created by cutting openings in a blank substrate strip or using a premade strip, either disposable or reusable, to create an SCF in step 621. Once the SCF is prepared, adhesive tape or other suitable backing material is affixed to the back side of the SCF in step 622. Next, the singulated substrates are inserted into the openings until they adhere to the adhesive in step 623. The newly created “strip” is optionally assembled and secured in the encapsulation cavity in step 624, and it is encapsulated in step 625. This could include, for instance, compression or transfer molding in some embodiments. Once encapsulated, the strip is removed from the encapsulation cavity in step 626. Finally, the adhesive material is removed, the SCF is optionally removed depending if it is disposable or reusable, external connectors, for example, but not limited to connection balls, pins, or nothing, are attached, and then the substrates (now packaged devices) are singulated in step 627. In some embodiments, process 620 may be performed using a disposable substrate carrier frame (DSCF).

FIG. 6C depicts a process 630 according to embodiments. In certain aspects, process 630 is an alternate method, which begins with using a substrate carrier frame (SCF) with openings and tabs in step 631. Next, singulated substrates, which may be populated or not, are inserted into the SCF openings in step 632, and secured using a back plate in step 633. The newly created “strip” is optionally assembled and secured in the encapsulation cavity in step 634, and is encapsulated in step 635. Once encapsulated, the strip is removed from the encapsulation cavity in step 636. Finally, the back plate is removed, the SCF is optionally removed depending if it is disposable or reusable, external connectors, for example, but not limited to connection balls, pins or nothing, are attached, and then the substrates (now packaged devices) are singulated in step 637. According to embodiments, one or more steps of FIGS. 6A-6D may be performed in a different order. For instance, step 633 may be performed by step 632.

FIG. 6D depicts a process 650 with two manufacturing flow options. In a first production flow, when multiple devices are on a substrate strip the flow has an input of (1) a substrate strip 651, and (2) the components 652. In this example, the flow has generally five stations: (1) SMT/Assembly 661, (2) molding or encapsulation 662, (3) ball or other connection attach 663, (4) singulation (cut apart or otherwise separate) 664, and (5) test 665. But as devices get more complex, some designs can no longer start with a strip made up of multiple substrates due to yield issues which result from the added complexity. The alternative is to cut (singulate) the good substrates out of the strip and process them individually (one at a time).

According to some embodiments, the substrate yield problem can be addressed by creating a substrate carrier frame 653 SCF. In the first manufacturing flow option, the manufacturing process is started with a substrate carrier frame (SCF) 653 populated with substrates 651. The normal production flow is then used to populate the good substrates 651 attached to the SCF 653 with components 652 before completing the remainder steps (662-665). Or if the only steps in the production flow that need the populated SCF are the mold step 662 and beyond (663-665), the substrate carrier frame may not need to be populated with assembled substrates 661b until the encapsulation step 662. In this second manufacturing flow option, the singulated substrates 651a are individually populated 661b with components 652 and then placed in SCFs 661b prior to molding/encapsulation 662. Independent of when in the process after mold 662 the substrates are singulated, they will need to be singulated 664 prior to being tested 665 in some embodiments.

One or more advantages of some embodiments are further illustrated with respect to FIG. 7, which includes snapshots at four different points in the semiconductor manufacturing process (A-D). In these examples, the starting point of the process is a blank multi-layer panel of substrates as shown at (A), is introduced to the production line. Here, two substrates 701, 702 have been identified as bad and “Xed” out. These two substrates will not be populated with components. The first process is to populate the electrically good substrates with components as shown at (B). Once the assembly process is completed, the whole panel is encapsulated with mold compound (C). The step after encapsulation, which is not shown in this sequence of pictures is to attach external connection balls to the back side of the substrates while still in the encapsulated panel. Finally, the substrates are cut apart (re-singulated), tested, and the electrically good SiP devices placed in a shipping tray as shown at (D).

In this sequence of pictures, it is noted that out of the 15 substrates started at the beginning of the process 13 were assembled correctly.

When the percentage of good electrical substrates on a panel is high enough, assembling multiple substrates on a panel could be cost-effective. But when the complexity of the substrate design reduces the yield to a few good substrates per panel, for instance as shown in FIG. 8 at (A), the batch process of a panel of substrates is no longer cost-effective. In this example, only four substrates are good out of 15, and the remainder are bad 801. The cause of the low yield is generally a result of the complexity of the substrates. The complexity becomes an issue when the substrate has an excessive number of trace layers, and the layout rules for each layer are tight in order to electrically connect all of the components. The typical solution for a low yield of a panel of substrates is to cut out the good substrates from the panel before the assembly process begins and take them through the assembly process one at a time (see (B) of FIG. 8, which shows a populated singulated substrate). Beyond the basic cost increase of assembling one at a time, the process step of encapsulating the substrates is replaced with attaching lids to the devices (see (C) of FIG. 8). A further complication that occurs is that to properly attach a lid to the substrate can increases the size of the substrate perhaps by 10 mm in both the X and Y dimensions significantly enlarging its size. As one of the significant advantages of SiP devices is a small footprint, an alternative lid process is to attach a lid which is the same size as the substrate, but to do so leaves a gap between the substrate and the lid (D).

The approach of one or more embodiments of this disclosure is to provide a method that allows the good substrates out of a low yielding substrate panel to be cut out of the panel (singulated) and combined with other good substrates in a Substrate Carrier Frame (SCF). By using the SCF approach, the assembly process becomes the same batch process on a panel as with high yield substrate panels. By using the SCF concept, not only is the existing issue of complexity resolved, but future issues of complexity will be resolved as the complexity of substrates continues to advance faster than advances in the manufacturing process.

According to embodiments, an SCF may contain substrates (e.g., GSSs) each with a different design. In certain aspects, the SCF assembly of GSSs makes prototyping easier.

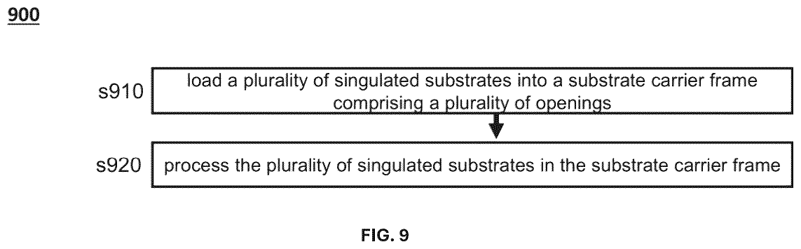

Referring now to FIG. 9, a process 900 is provided according to some embodiments. The process may comprise, loading (s910) a plurality of singulated substrates into a substrate carrier frame comprising a plurality of openings, and then processing (s920) the plurality of singulated substrates in the substrate carrier frame.

### SUMMARY OF EMBODIMENTS

A1. A method comprising: loading a plurality of singulated substrates into a substrate carrier frame comprising a plurality of openings; and processing (e.g., encapsulating) the plurality of singulated substrates in the substrate carrier frame.
A2. The method of A1, further comprising: attaching a plate to the loaded substrate carrier frame.
A3. The method of A1 or A2, wherein the singulated substrates are populated with one or more components mounted thereon before being loaded in the substrate carrier frame.
A4. The method of any of A1-A3, wherein processing the plurality of singulated substrates comprises placing the substrate carrier frame into a molding cavity and/or removing the substrate carrier frame from a molding cavity.
A5. The method of any of A1-A4, wherein processing comprises injection or compression molding to encapsulate the substrates.
A6. The method of any of A1-A5, wherein the singulated substrates are mounted on one or more retaining structures (e.g., tabs or ledges) within the openings of the substrate carrier frame.
A7. The method of any of A1-A6, further comprising: mounting one or more components on at least one of the plurality of singulated substrates (populating the substrates) while positioned in the substrate carrier frame.
A8. The method of any of A1-A7, further comprising: removing the encapsulated substrates from the substrate carrier frame (e.g., removing a panel of connected substrates post-molding); and singulating the encapsulated substrates to form a plurality of devices.
A9. The method of any of A1-A7, further comprising: singulating the encapsulated substrates to form a plurality of devices, wherein the singulating is performed while the encapsulated substrates are in the substrate carrier frame (e.g., wherein singulating comprises cutting the substrate carrier frame).
A10. The method of any of A1-A7, further comprising: removing individual encapsulated substrates from the substrate carrier frame (where the substrates are not interconnected following encapsulation).
A11. The method of any of A1-A10, wherein a first of the plurality of substrates is a different size than a second of the plurality of substrates.
A12. The method of any of A1-A11, further comprising: attaching at least one connection element (e.g., ball attach) to one or more of the substrates while in the substrate carrier frame.
A13. The method of any of A1-A12, further comprising: testing the singulated substrates before they are loaded into the substrate carrier frame.
A14. The method of any of A1 or A3-A13, wherein the substrate carrier frame comprises a bottom plate.
A15. The method of any of A1-A14, further comprising: applying an adhesive.
A16. The method of any of A1-A15, further comprising: cutting the plurality of openings in a blank strip to form the substrate carrier frame.
A17. The method of any of A1-A16, further comprising: molding the substrate carrier frame using compression molding; or molding the substrate carrier frame using transfer molding.
A18. The method of any of A1-A17, wherein two or more (e.g., each of) the plurality of singulated substrates has a unique design relative to the other singulated substrates.
B1. A device comprising: a singulated substrate; at least one component mounted on the substrate; an encapsulant; and a piece of a substrate carrier frame.
B2. The device of B1, wherein the device is manufactured according to any of A1-A18.
B3. The device of B1 or B2, wherein the substrate carrier frame is a device according to any of C1-C6 or D1-D15.
C1. A substrate carrier device comprising: a frame having a plurality of openings; and a bottom plate below the plurality of openings, wherein the openings are sized to receive a singulated substrate and the bottom plate is configured to support the singulated substrates.
C2. The device of C1, wherein the openings are separated by one or more rib portions of the frame.
C3. The device of C2, further comprising: one or more mold channels through the rib portions, wherein the mold channels connect two or more of the openings.
C4. The device of any of C1-C3, wherein:
(i) all of the openings are the same size, or
(ii) at least two of the openings are a different size.
C5. The device of any of C1-C4, further comprising: a singulated substrate placed in each of the openings.
C6. The device of C5, wherein the singulated substrate has at least one component mounted thereon.
D1. A substrate carrier device comprising: a frame having a plurality of openings; and at least one retainer (e.g., tab or ledge) within each of the plurality of openings.
D2. The device of D1, wherein the openings are separated by one or more rib portions of the frame.
D3. The device of D2, further comprising: one or more mold channels through the rib portions, wherein the mold channels connect two or more of the openings.
D4. The device of any of D1-D3, wherein:
(i) all of the openings are the same size, or
(ii) at least two of the openings are a different size.
D5. The device of any of D1-D4, wherein the openings are sized to receive a singulated substrate and the retainers are configured to support the singulated substrates.
D6. The device of any of D1-D5, wherein four retainers are provided in each of the plurality of openings (e.g., in each corner of the openings).
D7. The device of any of D1-D6, wherein:
(i) the retainers are provided at a bottom surface of the frame, or
(ii) the retainers are provided between an upper surface and lower surface of the frame and on an inner wall of the openings.
D8. The device of any of D1-D7, wherein the retainer is a ledge formed by a notch in the frame (e.g., in the rib portion).
D9. The device of D8, wherein the retainer fully surrounds an inner wall of the openings.
D10. The device of any of D1-D9, further comprising: a singulated substrate placed in each of the openings.
D11. The device of D10, wherein the singulated substrate has at least one component mounted thereon.
D12. The device of D11, wherein the at least one component is mounted on the underside of the substrate.
D13. The device of any of D1-D12, further comprising: a backplate.
D14. The device of D13, wherein the backplate is positioned over the openings (e.g., to secure the singulated substrates in the openings between the backplate and the retainers, where the substrates are inverted).
E1. The device of any of C1 to C6 or D1-D14, wherein the device is reusable or disposable.
F1. An apparatus for containing one or more singulated substrates, comprising: semiconductor processing equipment, wherein each opening is sized to contain a singulated substrate.
F2. The apparatus of F1, where each opening has one or more projections (e.g., ledges) extending from the sides of the opening for supporting a singulated substrate mounted/contained therein.
F3. The apparatus of F1, wherein each opening has a backplate at the base of each opening to support one or more singulated substrates mounted therein.
F4. The apparatus of F3, wherein the backplate is removable.
F5. The apparatus of F3 or F4, wherein the backplate comprises plastic, metal, or tape.
F6. The apparatus of any of F3-F5 wherein the backplate covers the entire back side of the panel.
F7. The apparatus of any of F1-F6, wherein two or more of the substrates in the apparatus have different designs or different component loads defining different device functionality.
G1. A method using the apparatus of any of F1-F7, comprising:
(i) wherein singulated substrates are inserted into apparatus populated with one or more components,
(ii) wherein populated singulated substrates are encapsulated, balls attached, and singulated as finished devices ready for final testing,
(iii) wherein singulated substrates are inserted into apparatus without components and singulated substrates are populated, encapsulated, balls attached and singulated as finished devices ready for final testing, and/or
(iv) wherein the plurality of openings on the apparatus are two or more sizes.
H1. A method for processing singulated substrates, comprising: removably locating a singulated substrate in an appropriately sized opening in a carrier sized to contain multiple the substrates (e.g., with retaining projections or tape) in the opening; installing components (populating) on the singulated substrates while located in the carrier openings; applying a restraining material to the bottom on the opening in the carrier; inverting the carrier; inserting the carrier into a conventional encapsulating equipment/machines; applying an encapsulant to the openings in the carrier to encapsulate the populated substrates; attaching connection elements (e.g., balls); removing the carrier from the machine; removing the restraining material; and removing the encapsulated, populated substrate from the carrier.

While various embodiments of the present disclosure are described herein, it should be understood that they have been presented by way of example only, and not by way of any limitation. Thus, the breadth and scope of the present disclosure should not be limited by any of the herein above-described exemplary embodiments. Moreover, any combination of herein above-described elements in all possible variations thereof is encompassed by the disclosure unless otherwise indicated herein or otherwise clearly contradicted by context. Accordingly, other embodiments, variations, and improvements not described herein are not excluded from the scope of the present disclosure. Such variations include but are not limited to new substrate material, different kinds of devices attached to the substrate not discussed, or new packaging concepts.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel.

1. A substrate carrier device comprising:
a frame comprising a plurality of openings that are sized to receive singulated substrates, wherein the openings are separated by one or more rib portions of the frame; and
an attachment, wherein the attachment is configured to support a singulated substrate when positioned in one of the openings.

2. The device of claim 1, further comprising:
one or more mold channels through the rib portions, wherein the mold channels connect two or more of the openings.

3. The device of claim 1, wherein all of the openings are the same size.

4. The device of claim 1, wherein at least two of the openings are a different size.

5. The device of claim 1, wherein retainers are provided in each of the corners of the plurality of openings.

6. The device of claim 1, wherein the device is reusable or disposable.

7. The device of claim 1, wherein the frame further comprises:
one or more alignment pins or holes suitable for and sized for use in semiconductor fabrication or assembly equipment.

8. An apparatus for containing one or more singulated substrates, comprising:
a panel having a plurality of openings therein; and
a plurality of alignment pins or holes,
wherein each opening is sized to contain a singulated substrate.

9. The apparatus of claim 8, where each opening has one or more projections extending from the sides of the opening for supporting a singulated substrate.

10. The apparatus of claim 9, wherein each opening has a backplate at the base of each opening to support one or more singulated substrates.

11. The apparatus of claim 10, wherein the backplate is removable.

12. A method for encapsulating populated singulated substrates comprising:
loading a plurality of populated singulated substrates into a substrate carrier frame having a plurality of openings, wherein each opening is configured to contain one of the plurality of singulated substrates; and
processing the plurality of singulated substrates in the substrate carrier frame to encapsulate the substrates.

13. The method of claim 12, wherein the singulated substrates are populated with one or more components mounted thereon before being loaded in the substrate carrier frame.

14. The method of claim 12, wherein processing the plurality of singulated substrates comprises at least one of placing the substrate carrier frame into a molding cavity or removing the substrate carrier frame from a molding cavity.

15. The method of claim 14, wherein the processing comprises injection or compression molding to encapsulate the substrates.

16. The method of claim 12, further comprising:
populating the substrates by mounting one or more components on at least one of the plurality of singulated substrates while positioned in the substrate carrier frame.

17. The method of claim 16, further comprising:
removing individual encapsulated substrates from the substrate carrier frame where the substrates are not interconnected following encapsulation.

18. The method of claim 12, wherein a first of the plurality of substrates is a different size than a second of the plurality of substrates.

19. The method of claim 12, further comprising:
attaching at least one exterior connection element to one or more of the substrates while in the substrate carrier frame.

20. The method of claim 12, further comprising:
applying a restraining material to the bottom of each of the openings in the carrier;
inverting the carrier;
inserting the carrier into encapsulating equipment;
applying an encapsulant to the openings in the carrier to encapsulate the populated substrates;
attaching connection elements;
removing the carrier from the equipment;
removing the restraining material; and
removing the encapsulated, populated substrate from the carrier.
